(19) United States
(12) Patent Application Publication
(10) Pub. No.: US 2015/0380633 A1
(43) Pub. Date: Dec. 31, 2015

(54) APPARATUS FOR DRIVING PIEZOELECTRIC ELEMENT AND METHOD FOR DRIVING PIEZOELECTRIC ELEMENT

(71) Applicant: Samsung Electro-Mechanics Co., Ltd., Suwon-si (KR)

(72) Inventor: Gyu Won KIM, Suwon-si (KR)

(73) Assignee: Samsung Electro-Mechanics Co., Ltd., Suwon-si (KR)

(21) Appl. No.: 14/636,304

(22) Filed: Mar. 3, 2015

(30) Foreign Application Priority Data
Jun. 26, 2014 (KR) 10-2014-0078752

(51) Int. Cl. H01L 41/04

(52) U.S. Cl. CPC H01L 41/042

(57) ABSTRACT

An apparatus for driving a piezoelectric element may include: a control unit outputting a plurality of digital values using a lookup table; and a digital-to-analog converting unit converting the plurality of digital values into plurality of analog signals, respectively, wherein the control unit selects a plurality of pieces of data from the lookup table at first intervals so as to output the plurality of pieces of data as the plurality of digital values, respectively.

### CROSS-REFERENCE TO RELATED APPLICATION

This application claims the priority and benefit of Korean Patent Application No. 10-2014-0078752 filed on Jun. 26, 2014, with the Korean Intellectual Property Office, the disclosure of which is incorporated herein by reference.

### BACKGROUND

The present inventive concept relates to an apparatus for driving a piezoelectric element and a method for driving a piezoelectric element.

Since a piezoelectric element driving technology involves driving a piezoelectric element based on a waveform of a current input, it has been widely used in the fields of a haptic technology, a motor replacement technology, and the like. In particular, the piezoelectric element driving technology has an advantage in that it may allow for the control of in greater degrees of precision and accuracy, as compared to a motor technology according to the related art.

In the piezoelectric element driving technology, an accurate output control of an output waveform applied to a piezoelectric element has become a significant issue. In detail, although a sine wave is used as the output waveform applied to the piezoelectric element, an output waveform actually generated by an apparatus for driving a piezoelectric element may be easily distorted.

Therefore, the generation of a precise output waveform is required for performing accurate controlling of the piezoelectric element, and consequently, the generation of an accurate output waveform has become a significant issue with respect to driving piezoelectric elements.

The following Patent Document relates to a direct digital frequency synthesizer using a linear interpolator and a counter and a frequency synthesizing method thereof, but this Patent Document does not satisfy the requirements for accuracy in the output waveform, as described above.

### RELATED ART DOCUMENT

Korean Patent Laid-Open Publication No. 2003-0053761

### SUMMARY

An aspect of the present inventive concept may provide an apparatus for driving a piezoelectric element and a method for driving a piezoelectric element capable of outputting a sine wave as an output waveform irrespective of a frequency of the output waveform and also improving a signal-to-noise ratio (SNR).

According to an aspect of the present inventive concept, an apparatus for driving a piezoelectric element may include: a control unit outputting using a lookup table; and a digital-to-analog converting unit converting the plurality of digital values into a plurality of analog signals, respectively, wherein the control unit selects a plurality of pieces of data from the lookup table at first intervals so as to output the plurality of pieces of data as the plurality of digital values, respectively.

According to another aspect of the present inventive concept, a method for driving a piezoelectric element may include: determining a first interval using a magnification of a reference frequency of a lookup table with respect to a frequency of an output waveform; selecting one a plurality of pieces of data stored in the lookup table at the first intervals; and converting the digital values into analog signals, respectively.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a configuration diagram illustrating an apparatus for driving a piezoelectric element according to an exemplary embodiment of the present inventive concept;

FIG. 2 is a diagram illustrating an example of signals output from respective components of the apparatus for driving the piezoelectric element illustrated in FIG. 1;

FIG. 3 is a configuration diagram illustrating a first example of a control unit of FIG. 1;

FIG. 4 is a configuration diagram illustrating a second example of the control unit of FIG. 1;

FIGS. 5A and 5B are diagrams for describing a search correction performed by the control unit of FIG. 4;

FIGS. 6A and 6B are graphs illustrating an example of an output waveform of FIGS. 5A and 5B;

FIG. 7 is a configuration diagram illustrating a third example of the control unit of FIG. 1;

FIGS. 8A and 8B are diagrams for describing an interval adjustment performed by the control unit of FIG. 7;

FIG. 9 is a flowchart illustrating a method for driving a piezoelectric element according to an exemplary embodiment of the present inventive concept; and

FIG. 10 is a flowchart illustrating a method for driving a piezoelectric element according to another exemplary embodiment of the present inventive concept.

### DETAILED DESCRIPTION

Hereinafter, exemplary embodiments in the present inventive concept will be described in detail with reference to the accompanying drawings.

The inventive concept may, however, be exemplified in many different forms and should not be construed as being limited to the specific embodiments set forth herein. Rather, these embodiments are provided so that this inventive concept will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

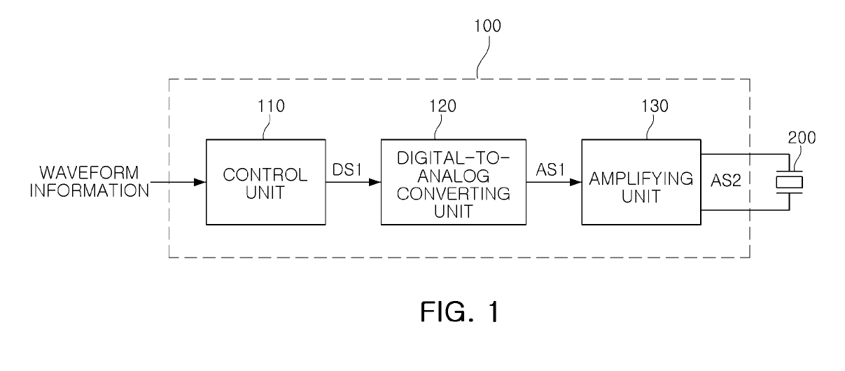

FIG. 1 is a configuration diagram illustrating an example of an apparatus for driving a piezoelectric element according to the present inventive concept.

Referring to FIG. 1, an apparatus 100 for driving a piezoelectric element may include a control unit 110 and a digital-to-analog converting unit 120. According to exemplary embodiments, the apparatus 100 for driving the piezoelectric element may further include an amplifying unit 130.

The control unit 110 may output a digital value DS1 for generating an output waveform using a lookup table. The control unit 110 may select a piece of data from the lookup table at first intervals, and may output the piece of data as the digital value.

The digital-to-analog converting unit 120 may convert the digital value DS1 into an analog signal AS1.

The amplifying unit 130 may amplify the input analog signal AS1 to provide the amplified analog signal AS1 to a piezoelectric element 200.

In the exemplary embodiment, the amplifying unit 130 may differentially amplify the input analog signal AS1 so as to output a pair of analog signals AS2.

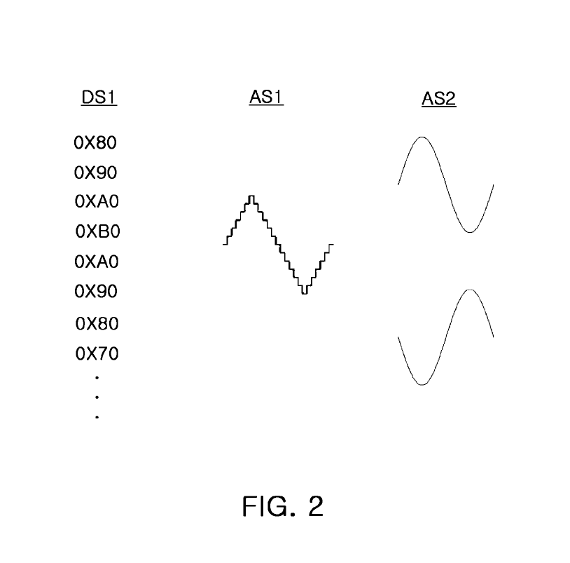

Signals output from respective components of such an apparatus for driving a piezoelectric element are as illustrated in FIG. 2.

As illustrated in FIG. 2, the control unit 110 may output the digital value DS1 using the lookup table.

The digital-to-analog converting unit 120 may convert the digital value DS1 into the analog signal AS1 to output the analog signal AS1. Since the digital-to-analog converting unit 120 converts the digital value into the analog signal to output the analog signal, the analog signal AS1 may be a sine wave having a form of a step function as illustrated in FIG. 2.

The amplifying unit 130 may be provided as a differential amplifier. The amplifying unit 130 may filter the input analog signal AS1 and may generate two sine waves AS2 having opposite phases, so as to provide the two sine waves AS2 to both input terminals of the piezoelectric element 200, respectively.

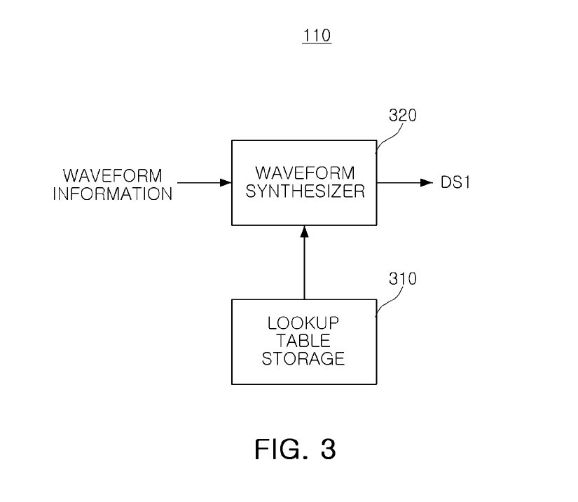

FIG. 3 is a configuration diagram illustrating a first example of the control unit of FIG. 1.

Referring to FIG. 3, the control unit 110 may include a lookup table storage 310 and a waveform synthesizer 320.

The lookup table storage 310 may store a plurality of pieces of data of the lookup table. The lookup table may include a plurality of pieces of data capable of generating a reference waveform at a preset reference frequency.

The waveform synthesizer 320 may receive waveform information on an output waveform, may select a digital value for generating the output waveform from the lookup table, and may output the digital value. The waveform synthesizer 320 may determine a first interval using a magnification of the reference frequency with respect to a frequency of the output waveform, may select one of the plurality of pieces of data at the first intervals, and may output the selected piece of data as the digital value.

Hereinafter, a case in which the reference waveform of the lookup table is a sine wave having a frequency of 7.8125 hertz (Hz) when the reference frequency of the lookup table is 8 kilohertz (kHz) will be described by way of example.

Since the reference frequency of the lookup table is 8 kHz, in a case in which sampling is performed using the reference waveform having the frequency of 7.8125 Hz as the reference frequency, the lookup table may have a total of 1024 pieces of data, that is, 1024 digital values.

Byway of example, in a case in which the output waveform of the apparatus 100 for driving the piezoelectric element has the same frequency as the frequency of the reference waveform of the lookup table, for example, 7.8125 Hz, the control unit 110 may sequentially output the 1024 digital values DS1 included in the lookup table at intervals of 8 kHz. That is, the first interval in this case may be ‘1’.

As another example, in the case in which the output waveform of the apparatus 100 for driving the piezoelectric element has a frequency of 15.625 Hz, the control unit 110 may have a first interval different from that of the example described above. That is, since the output waveform of the apparatus 100 for driving the piezoelectric element has the frequency of 15.625 Hz, the frequency of the output waveform of the apparatus 100 for driving the piezoelectric element is two times greater than the frequency of the reference waveform of the lookup table, that is, 7.8125 Hz. Therefore, in this case, all of the digital values in the lookup table are not used. Since the control unit 110 is to form the output waveform having the frequency of 15.625 Hz by outputting the digital values DS1 in the lookup table at the intervals of 8 kHz, the control unit 110 may only use 512 pieces of data from among the 1024 pieces of data in the lookup table. That is, the control unit 110 may generate a single period of the output waveform having the frequency of 15.625 Hz by sequentially outputting digital values stored only in odd numbered sequences (or only in even numbered sequences) from among the plurality of pieces of data in the lookup table at the intervals of 8 kHz. In this case, the first interval may be ‘2’. That is, the control unit 110 may select and output the plurality of pieces of data in the lookup table at the intervals of ‘2’.

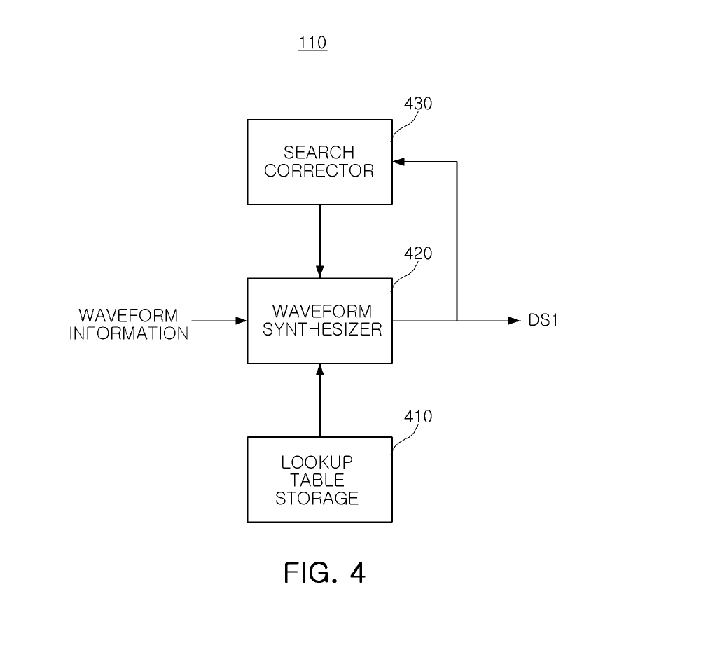

FIG. 4 is a configuration diagram illustrating a second example of the control unit of FIG. 1.

In the second example of FIG. 4, once a sequential search at the first intervals is completed with respect to the entire lookup table, the control unit 110 may determine a position for re-starting an additional search by reflecting the number of pieces of data in the lookup table remaining in the last search.

Referring to FIG. 4, the control unit 110 may further include a lookup table storage 410, a waveform synthesizer 420, and a search corrector 430. Since a description of the lookup table storage 410 and the waveform synthesizer 420 corresponds to that of the lookup table storage 310 and the waveform synthesizer 320 described with reference to the aforementioned first example in FIG. 3, a repeated description thereof will be omitted for conciseness.

The search corrector 430 may determine a position for re-starting an additional search with respect to a lookup table subsequently to digital values being selected with respect to all of the pieces of data in the lookup table. That is, once the sequential search at the first intervals is completed with respect to all of the plurality of pieces of digital data in the lookup table, the search corrector 430 may determine the position for re-starting the additional search by reflecting the number of pieces of data remaining in the last search.

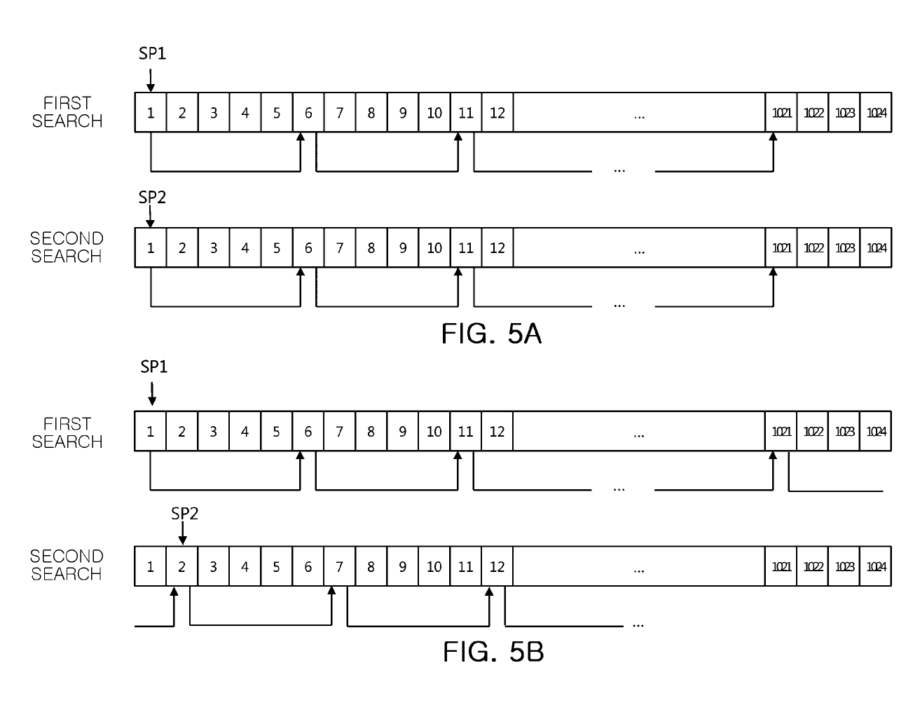

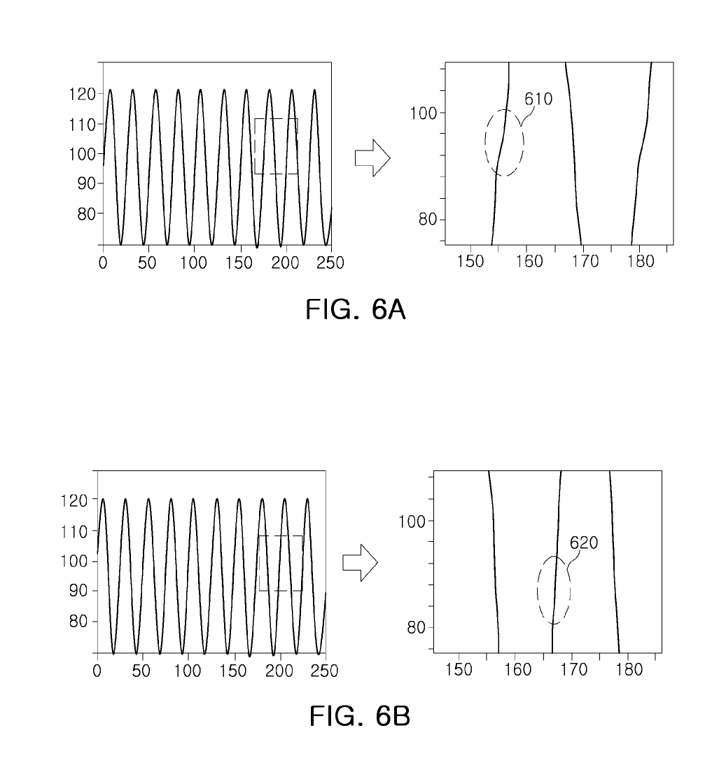

Hereinafter, the second example of the control unit will be described in greater detail with reference to FIGS. 5A and 5B and 6A and 6B.

FIGS. 5A and 5B are diagrams for describing the search corrector of FIG. 4, wherein FIG. 5A illustrates an example in which a search correction is not performed and FIG. 5B illustrates an example in which the search correction is performed.

Referring to FIG. 5A, an example in which digital values are selected and output with respect to the lookup table having 1024 pieces of data at intervals of ‘5’ is illustrated. That is, subsequently to a position at which an initial digital value is output being set as a position SP1 and the initial digital value is output, the digital values may be output at intervals of ‘5’. Therefore, in a case in which a 1021-th piece of data in the lookup table is output, the digital values may be output with respect to the entire data in the lookup table at the intervals of ‘5’. In a case in which a second search, that is, a second period of the output waveform is commenced, the initial digital value in the lookup table may be re-set as a position SP2, and the outputting process described above may be reiterated.

Meanwhile, FIG. 5B illustrates the second example of the control unit in which the search correction of FIG. 4 is performed.

Referring to FIG. 5B, similar to those described above with reference to FIG. 5A, digital values may be selected and output with respect to the lookup table having 1024 pieces of data at intervals of ‘5’. That is, the waveform synthesizer 420 may select and output the digital values at the first intervals of ‘5’ with respect to the lookup table. Once a sequential search at the first intervals is completed with respect to the entire lookup table, the search corrector 430 may determine a position SP2 for re-starting an additional search by reflecting the number of pieces of data in the lookup table remaining in the last search. That is, since the number of remaining pieces of data is 3 in the first search, a position of a second piece of data in the lookup table may be determined as the position SP2 for re-starting the additional search by maintaining the first interval with respect to the remaining pieces of data.

Therefore, in the case in which the additional search is performed for the digital values with respect to the entire lookup table, for example, even in the case in which a new period of the output waveform is commenced, the search corrector 430 may perform the correction so as to maintain the first interval.

FIGS. 6A and 6B illustrate examples of an output waveform of FIGS. 5A and 5B.

FIG. 6A illustrates an example of an output by FIG. 5A, and it may be seen that a predetermined error occurs in an output waveform as indicated by a portion denoted by reference numeral 610. It may be understood that such an error occurs since the first interval is not maintained at the time of starting a second search with respect to the lookup table.

On the other hand, FIG. 6B illustrates an example of an output by FIG. 5B, and it may be seen that an error is absent in an output waveform as indicated by a portion denoted by reference numeral 620. In detail, the output waveform may have uniformity since the first interval is maintained by the search corrector 430 in any case.

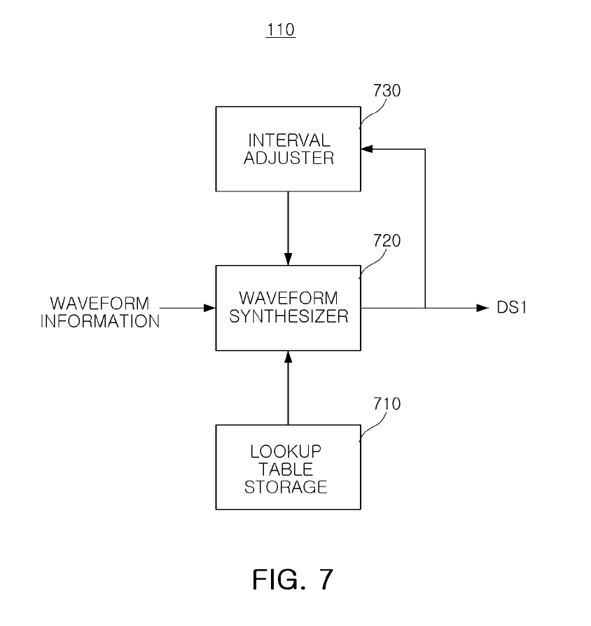

FIG. 7 is a configuration diagram illustrating a third example of the control unit of FIG. 1.

In the third example of FIG. 7, in a case in which digital values output at first intervals do not include a digital value corresponding to a maximum value or a minimum value of the lookup table, the control unit 110 may adjust the first interval.

Referring to FIG. 7, the control unit 110 may include a lookup table storage 710, a waveform synthesizer 720, and an interval adjuster 730. Since a description of the lookup table storage 710 and the waveform synthesizer 720 corresponds to that of the lookup table storage 310 and the waveform synthesizer 320 described with reference to the first example in FIG. 3, a repeated description thereof will be omitted for conciseness.

In the case in which the digital values output at the first intervals do not include the digital value corresponding to the maximum value or the minimum value of the lookup table, the interval adjuster 730 may adjust the first interval.

In the exemplary embodiment, the interval adjuster 730 may include a memory storing the maximum digital value and the minimum digital value, and an interval reducer reducing the first interval in the case in which the digital values output from the waveform synthesizer 720 do not include the digital value corresponding to the maximum digital value or the minimum digital value in the lookup table.

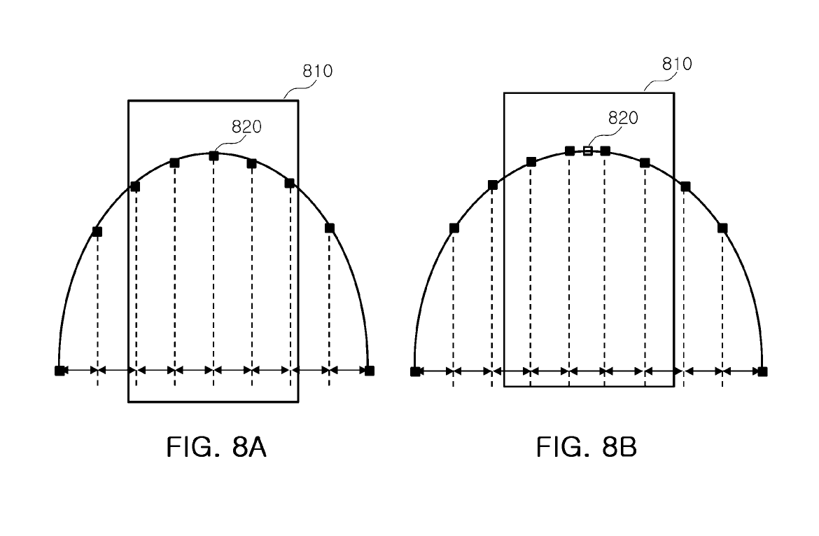

FIGS. 8A and 8B are views for describing an interval adjustment by the control unit of FIG. 7. Hereinafter, a third example of the control unit will be described in greater detail with reference to FIGS. 8A and 8B.

FIGS. 8A and 8B illustrate a case in which digital values are output at equidistant first intervals so as to form an output waveform. Plotted points illustrated in FIGS. 8A and 8B are the digital values selected by the control unit, and it may be seen that the digital values are selected at the equidistant first intervals as illustrated in FIGS. 8A and 8B.

It may be seen from FIG. 8A that a maximum digital value 820 is selected by the control unit. In this case, since the maximum digital value is included in the output waveform, the output waveform may be accurately generated.

Meanwhile, it may be seen from FIG. 8B that the maximum digital value 820 is not selected by the control unit. That is, since the maximum digital value is present between the first intervals, the maximum digital value 820 is not selected by the control unit in the case of FIG. 8B. In this case, it may be said that a possibility of noise being present in the output waveform is higher than in the case of FIG. 8A.

Therefore, in the case of FIG. 8B, that is, in the case in which the digital values output from the waveform synthesizer 720 do not include the digital value corresponding to the maximum value or the minimum value of the lookup table, the interval adjuster 730 may reduce the first interval.

In the exemplary embodiment, the waveform synthesizer 720 may preset a minimum range of a maximum range 810 of the waveform synthesizer 720. The waveform synthesizer 720 may verify whether or not the digital value that is currently selected is included in the maximum range 810 or the minimum range of the output waveform. In a case in which the digital value that is currently selected is included in the maximum range 810 or the minimum range, the waveform synthesizer 720 may verify whether or not to the digital value that is currently selected corresponds to the maximum range 810 or the minimum range. In a case in which the digital value that is currently selected does not correspond to the maximum range 810 or the minimum range, the waveform synthesizer 720 may reduce the first interval.

On the other hand, in a case in which the digital value that is currently selected does is not included in the maximum range 810 or the minimum range, the waveform synthesizer 720 may maintain the first interval.

The components described above, for example, the control unit 110, the digital-to-analog converting unit 120, the amplifying unit 130, and the sub-components thereof may be configured as a single circuit unit or a discreet circuit unit, for example, a discreet integrated circuit.

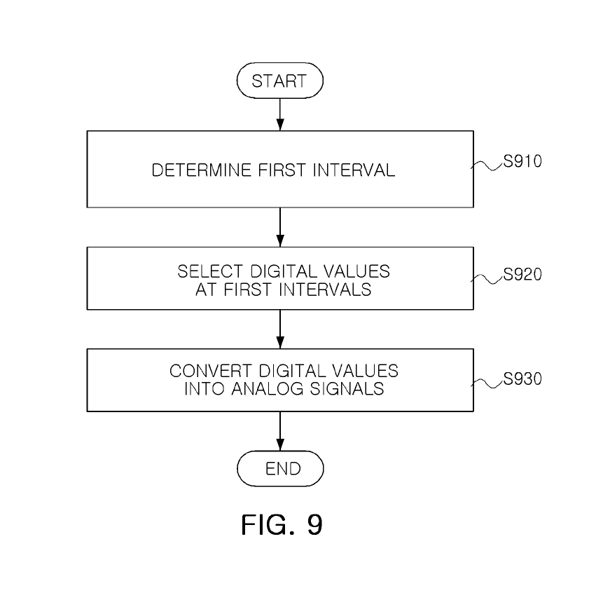

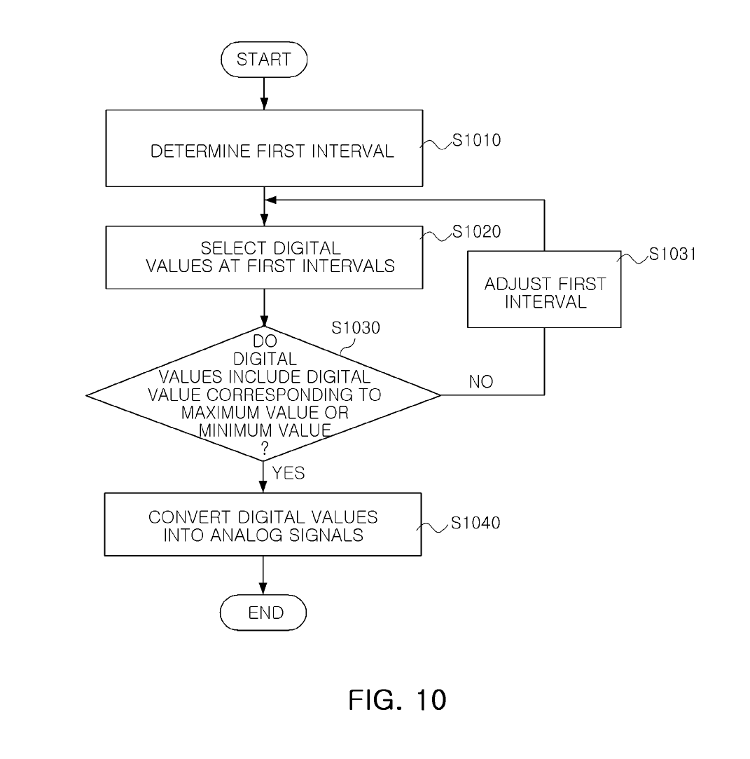

Hereinafter, various examples of a method for driving a piezoelectric element according to an exemplary embodiment of the present inventive concept will be described with reference to FIGS. 9 and 10. However, since the various examples of the method for driving the piezoelectric element are performed by the apparatus for driving the piezoelectric element described above with reference to FIGS. 1 through 8, a description identical to or equivalent to the above-mentioned description will be omitted for conciseness.

FIG. 9 is a flowchart for describing an example of a method for driving a piezoelectric element according to an exemplary embodiment of the present inventive concept.

Referring to FIG. 9, in operation 5910, the apparatus 100 for driving the piezoelectric element may determine a first interval with respect to a frequency of an output waveform using a magnification of a reference frequency of a lookup table.

The apparatus 100 for driving the piezoelectric element may select digital values at the first intervals from plurality of pieces of data stored in the lookup table in operation S920, and may convert the digital values into analog signals, respectively, in operation S930.

In operation S920, the apparatus 100 for driving the piezoelectric element may perform a sequential search at the first intervals for the entire lookup table, and may determine a position for re-starting an additional search by reflecting the number of pieces of data in the lookup table remaining in the last search.

FIG. 10 is a flowchart for describing another example of a method for driving a piezoelectric element according to another exemplary embodiment of the present inventive concept.

Referring to FIG. 10, in operation S1010, the apparatus 100 for driving the piezoelectric element may determine a first interval with respect to a frequency of an output waveform using a magnification of a reference frequency of a lookup table ( ).

The apparatus 100 for driving the piezoelectric element may select digital values at the first intervals from plurality of pieces of data stored in the lookup table in operation S1020, and may determine whether or not the digital values output at the first intervals include a digital value corresponding to a maximum digital value or a minimum digital value of the lookup table in operation S1030.

In a case in which the digital values do not include the digital value corresponding to the maximum digital value or the minimum digital value of the lookup table as denoted by “No” in operation S1030, the first interval may be adjusted in operation S1031.

In a case in which the digital values include the digital value corresponding to the maximum digital value or the minimum digital value of the lookup table as denoted by “Yes” in operation S1030, the digital values may be converted into the analog signals, respectively, in operation S1040.

As set forth above, according to exemplary embodiments of the present inventive concept, the output waveform may be output as the sine wave irrespective of the frequency of the output waveform and the SNR may also be improved.

While exemplary embodiments have been shown and described above, it will be apparent to those skilled in the art that modifications and variations could be made without departing from the scope of the present invention as defined by the appended claims.

What is claimed is:

1. An apparatus for driving a piezoelectric element, the apparatus comprising:
a control unit outputting a plurality of digital values using a lookup table; and
a digital-to-analog converting unit converting the plurality of digital values into a plurality of analog signals, respectively,
wherein the control unit selects a plurality of pieces of data from the lookup table at a first interval so as to output the plurality of pieces of data as the plurality of digital values, respectively.

2. The apparatus of claim 1, wherein when a sequential search at the first intervals is completed for the entire lookup table, the control unit determines a position for re-starting an additional search by reflecting a number of pieces of data in the lookup table remaining in a last search.

3. The apparatus of claim 1, wherein the control unit determines the first interval using a magnification of a reference frequency of the lookup table with respect to a frequency of an output waveform.

4. The apparatus of claim 1, wherein when the plurality of digital values output at the first intervals do not include a digital value corresponding to a maximum value or a minimum value in the lookup table, the control unit adjusts the first interval.

5. The apparatus of claim 1, wherein the control unit includes:
a lookup table storage storing a plurality of pieces of data determined based on a reference frequency; and
a waveform synthesizer determining the first interval using the magnification of the reference frequency with respect to the frequency of the output waveform, selecting one of the plurality of pieces of data at the first intervals, and outputting the selected piece of data as the digital value.

6. The apparatus of claim 5, wherein the control unit further includes a search corrector determining a position for re-starting an additional search by reflecting the number of pieces of data remaining in the last search when the sequential search at the first intervals is completed with respect to all of the plurality of pieces of data.

7. The apparatus of claim 5, wherein the control unit further includes an interval adjuster adjusting the first interval in a case in which the digital values output at the first intervals do not include a digital value corresponding to a maximum digital value or a minimum digital value in the lookup table.

8. The apparatus of claim 7, wherein the interval adjuster includes:
a memory storing the maximum digital value and the minimum digital value; and
an interval reducer reducing the first interval in a case in which the digital values output from the waveform synthesizer do not include the digital value corresponding to the maximum digital value or the minimum digital value in the lookup table.

9. A method for driving a piezoelectric element, the method comprising:
determining a first interval using a magnification of a reference frequency of a lookup table with respect to a frequency of an output waveform;
selecting one of a plurality of pieces of data stored in the lookup table at the first intervals and outputting the selected piece of data as a digital value; and
converting the digital value into an analog signal.

10. The method of claim 9, wherein the outputting of the selected piece of data as the digital value includes:
performing a sequential search at the first intervals with respect to the entire lookup table; and
determining a position for re-starting an additional search by reflecting a number of pieces of data in the lookup table remaining in a last search.

11. The method of claim 9, further comprising adjusting the first interval in a case in which the digital values output at the first intervals do not include a digital value corresponding to a maximum digital value or a minimum digital value in the lookup table.

12. The method of claim 11, wherein the adjusting of the first interval includes:
storing the maximum digital value and the minimum digital value;
determining whether or not the digital value currently selected is included in a maximum range or a minimum range of the output waveform; and
reducing the first interval in a case in which the digital value currently selected is included in the maximum range or the minimum range, and the digital value currently selected does not correspond to the maximum digital value or the minimum digital value.

13. The method of claim 12, wherein the adjusting of the first interval further includes restoring the reduced first interval to the interval prior to the reduction thereof in a case in which the digital value currently selected is not included in the maximum region or the minimum region subsequently to the reduction of the first interval.
